(19) United States
(12) Patent Application Publication
(10) Pub. No.: US 2024/0296901 A1
(43) Pub. Date: Sep. 5, 2024

(54) SEMICONDUCTOR DEVICE, CONTROL METHOD FOR SEMICONDUCTOR DEVICE AND CONTROL PROGRAM

(71) Applicant: Renesas Electronics Corporation, Tokyo (JP)

(72) Inventor: Takuro NISHIKAWA, Tokyo (JP)

(21) Appl. No.: 18/435,406

(22) Filed: Feb. 7, 2024

(30) Foreign Application Priority Data
Mar. 2, 2023 (JP) 2023-031461

(51) Int. Cl. G11C 29/56

(52) U.S. Cl. CPC G11C 29/56008; G11C 29/56004; G11C 2029/5602

(57) ABSTRACT

A failure analysis device is for analyzing a failure of the semiconductor device equipped with a logic circuit and a memory circuit. It has a storage device and a processor. The storage device stores fail bit data obtained by testing the memory circuit and failure diagnosis data obtained by failure diagnosis for test results of the logic circuit. The processor extracts a fail I/O value from the fail bit data, extracts the data of the memory connection port which is the connection port to the memory circuit from among the estimated failure parts included in the failure diagnosis data, and determines match/not-match between the fail I/O value and the port ID value included in the data of the memory connection port.

### BACKGROUND

The present invention relates to a semiconductor device, a control method of the semiconductor device, and a control program, for example, a semiconductor device suitable for receiving a signal with high accuracy by suppressing the influence of noise, a control method of the semiconductor device, and a control program.

There is disclosed technique listed below.
[Patent Document 1] Japanese Unexamined Patent Application Publication No. 2010-193085

Patent Document 1 discloses a communication device for communicating with an external device using a Manchester-coded signal. In the communication device as disclosed in Patent Document 1, further noise countermeasures are required.

### SUMMARY

A semiconductor device according to the present disclosure comprises a receiver for receiving a differential signal and converting the received signal to logic value is expressed by the pulse waveform, and a control circuit for performing predetermined processing on the basis of the received signal. The receiver includes an edge detection circuit for detecting an edge of the differential signal, a pulse generating circuit for generating a one-shot pulse of a predetermined width and outputting as the received signal at a timing at which the edge is detected by the edge detection circuit, and a pulse adjusting circuit for adjusting a predetermined width of the one-shot pulse generated by the pulse generating circuit.

A control method of a semiconductor device according to the present disclosure includes a transmitter, a receiver that receives the differential signal and converts the received signal logic value is expressed by the pulse waveform, and a control circuit for performing predetermined processing on the basis of the received signal. When the operation mode is a test mode, the test data is generated from the control circuit, and outputs a differential signal corresponding to the test data from the transmission circuit, In the receiver, detects the edge of the differential signal output from the transmission circuit. In the receiver, a one-shot pulse of a predetermined width at the timing of detecting the edge, and outputs as a received signal, In the receiver, the test data, and the received signal corresponding to the test data, on the basis of the comparison result, adjusts the predetermined width of the one-shot pulse.

A control program according to the present disclosure is a control program for executing the processing in a semiconductor device. The semiconductor device comprises a receiver for receiving a differential signal, and a control circuit for performing a predetermined processing on the basis of the received signal. When the operation mode is a test mode, the computer performs the following processing.
(1) A processing for generating test data from the control circuit
(2) A processing for outputting a differential signal corresponding to the test data from the transmission circuit
(3) In the receiver, a processing for generating a one-shot pulse of a predetermined width at the timing of detecting the edge and a processing for outputting as a received signal, (4) In the receiver, a processing for adjusting the predetermined width of the one-shot pulse based on a result of a comparison the test data with the received signal corresponding to the test data

The present disclosure can provide a semiconductor device capable of accurately receiving a signal by suppressing the influence of noise, a control method of a semiconductor device, and a control program.

### BRIEF DESCRIPTION OF THE DRAWINGS

FIG. 1 is a block diagram showing a configuration example of a communication system provided with a semiconductor device according to a first embodiment.

FIG. 2 is a block diagram showing a configuration example of a receiver provided in the semiconductor device according to the first embodiment.

FIG. 3 is a timing chart showing the operation before the pulse width adjustment of the semiconductor device according to the first embodiment.

FIG. 4 is a timing chart showing the operation before the pulse width adjustment of the semiconductor device according to the first embodiment.

FIG. 5 is a flowchart showing the operation in the test mode of the semiconductor device according to the first embodiment.

FIG. 6 is a timing chart showing the operation of the semiconductor device according to the first embodiment.

FIG. 7 is a block diagram showing a modification of the receiver provided in the semiconductor device according to the first embodiment.

FIG. 8 is a circuit diagram showing a configuration example of a slew rate control unit.

FIG. 9 is a block diagram showing a configuration example of a semiconductor device according to a second embodiment.

FIG. 10 is a circuit diagram showing a configuration example of a delay circuit.

FIG. 11 is a block diagram showing a configuration example of a semiconductor device according to a third embodiment.

FIG. 12 is a timing chart showing the operation before the pulse width adjustment of the semiconductor device according to the third embodiment.

FIG. 13 is a timing chart showing the operation after the pulse width adjustment of the semiconductor device according to the third embodiment.

### DETAILED DESCRIPTION

Hereinafter, an embodiment will be described with reference to the drawings. Since the drawings are simplified, the technical scope of the embodiment should not be narrowly interpreted on the basis of the description of the drawings. Further, the same elements are denoted by the same reference numerals, without redundant description.

In the following embodiments, where it is necessary for convenience, it will be described by dividing it into multiple sections or embodiments. However, unless otherwise specified, they are not mutually related, one is in the relationship of some or all modifications of the other, examples of application, detailed description, supplemental explanation, etc. In the following embodiments, the number of elements, etc. (including the number of elements, numerical values, quantities, ranges, etc.) is not limited to the specific number, but may be not less than or equal to the specific number, except for cases where the number is specifically indicated and is clearly limited to the specific number in principle.

Furthermore, in the following embodiments, the constituent elements (including the operation steps and the like) are not necessarily essential except in the case where they are specifically specified and the case where they are considered to be obviously essential in principle. Similarly, in the following embodiments, when referring to the shapes, positional relationships, and the like of components and the like, it is assumed that the shapes and the like are substantially approximate to or similar to the shapes and the like, except for the case in which they are specifically specified and the case in which they are considered to be obvious in principle, and the like. The same applies to the above-mentioned numbers and the like, including the number, the numerical value, the amount, the range, and the like.

### First Embodiment

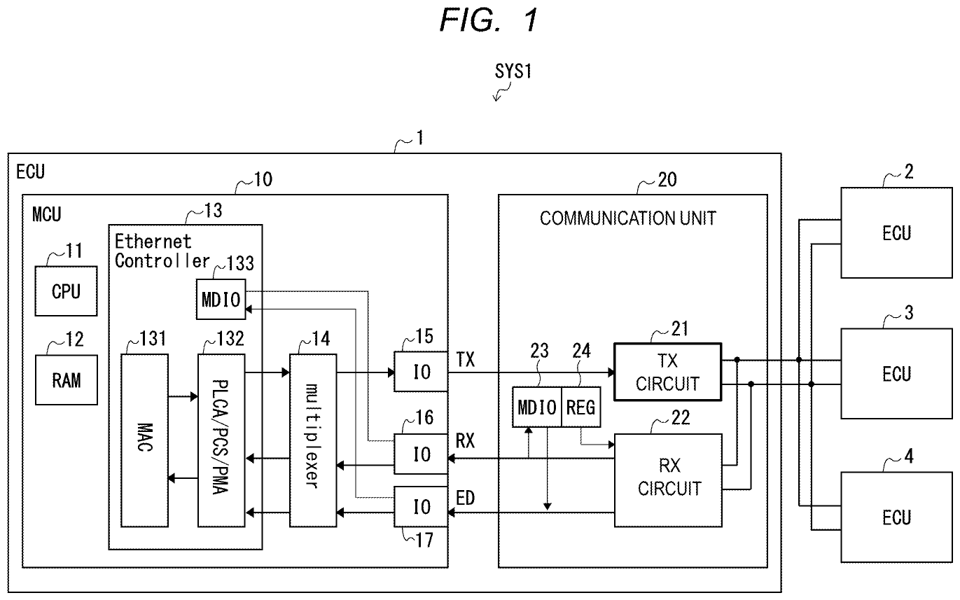

FIG. 1 is a block diagram illustrating a configuration of a communication system SYS1 including an ECU (semiconductor device) 1 according to a first embodiment. ECU is an abbreviation for Electronic Control Unit.

As shown in FIG. 1, the communication SYS1 includes the ECUs 1 to 4. The ECUs 1 to 4 communicate with each other via a communication cable. As an example, Ether 10base-t1s specified in IEEE802.2cg are employed in the ECUs 1 to 4. Therefore, as communication cable, relatively susceptible UTP (Unshielded Twisted Pair) cable is used. The ECUs 1 to 4 also communicate using Manchester coded differential signaling. Then, each of the ECUs 1 to 4 converts the received differential signal into an RZI (Return to Zero Inversion) encoded signal to perform a predetermined process. Here, RZI encoded signal is susceptible to noises because the logical value is represented by a pulse-waveform. Therefore, in the communication system SYS1, it is required to accurately receive a signal by suppressing the effect of noise.

The ECU 1 includes an MCU (control circuit) 10, a communication unit 20. MCU is an abbreviation for Micro Controller Unit.

The MCU 10 is formed on the chip separately from the communication unit 20. The MCU 10 includes a CPU (Central Processing Unit) 11, a RAM (Random Access Memory) 12, an Ethernet controller 13, a multiplexer 14, and IOs 15 to 17. The Ethernet controller 13 includes a MAC unit 131, a PLCA/PCS/PMA 132, and an MDIO 133. MAC is an abbreviation for Media Access Control. PLCA is an abbreviation for Physical Layer Collision Avoidance. The PCS is an abbreviation for Physical Coding Sublayer. PMA is an abbreviation for Physical Medium Attachment. MDIO is an abbreviation for Management Data Input/Output.

The communication unit 20 includes a transmitter 21, a receiver 22, an MDIO 23, and a register 24.

In the MCU 10, the Ethernet controller 13 receives an instruction from CPU 11, for example, and outputs the transmitted data TX to the communication unit 20 through the multiplexer 14 and the IO 15. In the communication unit 20, the transmitter 21 converts the transmission data TX into Manchester-coded differential signals and transmits them to the ECUs 2 to 4, which is an external device, through a communication cable. In the communication unit 20, the receiver 22 receives the Manchester-encoded differential signal transmitted from any one of the ECUs 2 to 4, via a communication cable, converts RZI encoded signal (received signal) RX to be outputted.

Incidentally, the pulse width of the pulse waveform included in RZI encoded signal RX, in the default state, is determined by the setting value X. The setting value X is transferred from the MDIO 133 of the Ethernet controller 13 to the MDIO 23 of the communication unit 20, and stored in the register 24. The receiver 22, the signal ED representing whether the magnitude of the received differential signal is equal to or greater than a predetermined value, and outputs the signal RX. In the MCU 10, the Ethernet controller 13 receives the signal RX via the IO 16 and the multiplexer 14 and receives the signal ED via the IO 17 and the multiplexer 14.

Here, if it is represented by the signal ED that the magnitude of the differential signal is equal to or greater than a predetermined value, the Ethernet controller 13 determines that the received signal RX is highly reliable and performs a predetermined process in accordance with the received signal RX. In contrast, if the signal ED indicates that the magnitude of the differential signal is less than the predetermined value, the Ethernet controller 13 determines that the received signal RX is not reliable and does not perform a predetermined process according to the received signal RX.

### (Example of Configuration of the Receiver 22)

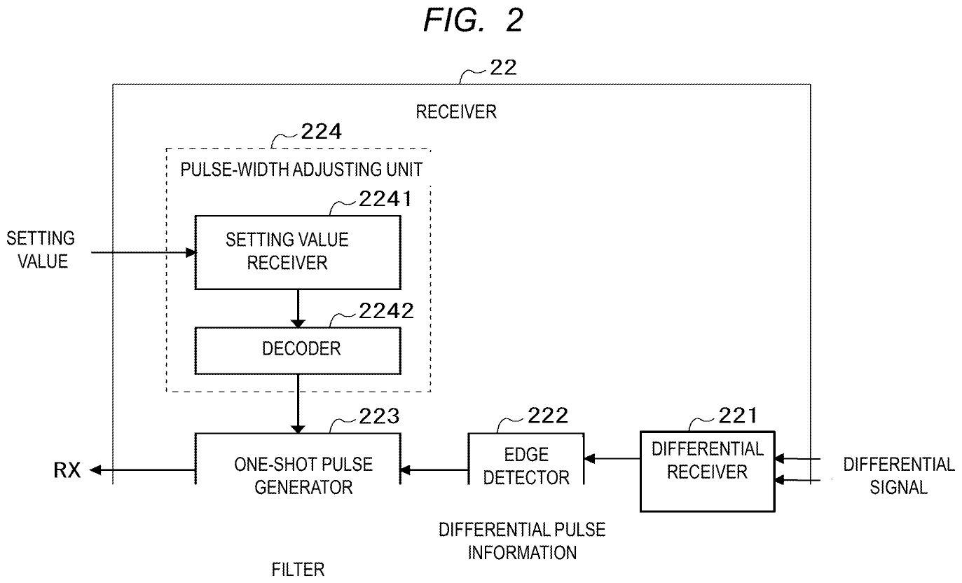

FIG. 2 is a block diagram showing a configuration example of a receiver 22. As shown in FIG. 2, the receiver 22 includes a differential receiver 221, an edge detector 222, a one-shot pulse generator 223, a pulse width adjusting unit 224, and a filter (filtering circuit) 225. The pulse width adjusting unit 224 includes a setting value receiver 2241 that receives the setting value X stored in the register 24 and a decoder 2242 that decodes the setting value X.

The differential receiver 221 receives the Manchester coded differential signal. The edge detector 222 detects the edge of the differential signal received by the differential receiver 221. The one-shot pulse generator 223 is, for example, a monostable multivibrator, and generates a one-shot pulse of a predetermined width set by the pulse width adjusting unit 224 at a timing at which an edge is detected by the edge detector 222 and outputs the one-shot pulse as a signal (received signal) RX that is RZI encoded.

The pulse width adjusting unit 224 is configured to adjust the pulse width of the pulse included in the received signal RX based on an instruction from the MCU 10. The adjustment method of the pulse width using the pulse width adjusting unit 224 will be described later. The filter 225, by passing only the maximums of the two signals constituting the differential signal, and outputs a signal ED representing the magnitude of the differential signal.

### (Operation Before Pulse Width Adjustment)

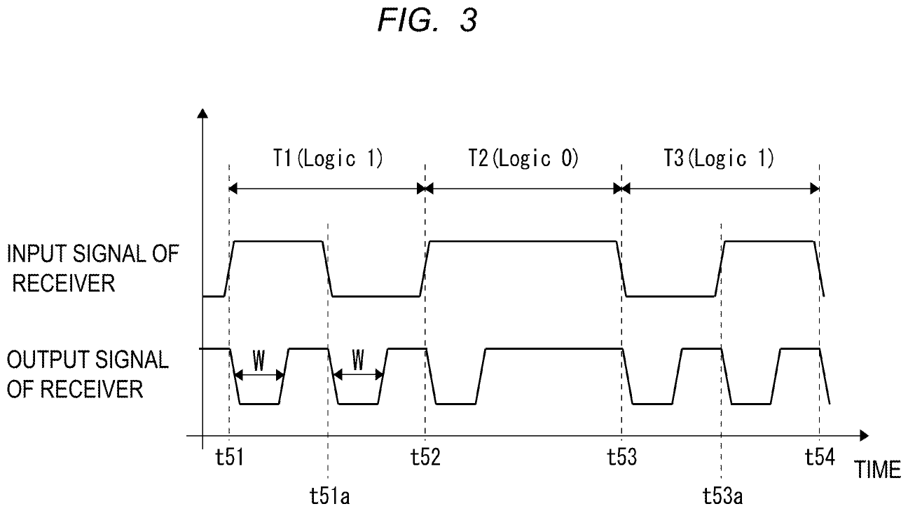

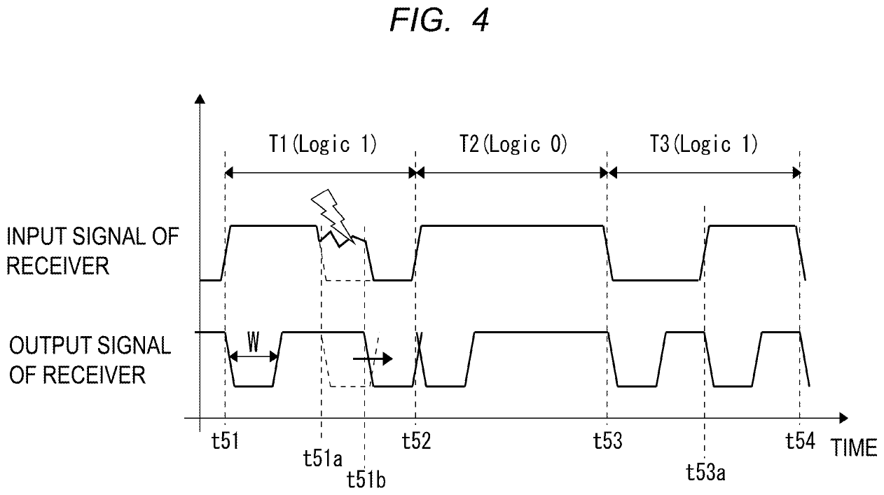

FIGS. 3 and 4 are timing charts showing the operation of the ECU 1 prior to pulse-width adjustment. FIG. 3 shows an example in which no noise is generated, and FIG. 4 shows an example in which noise is generated. Further, in the example of FIGS. 3 and 4, for simplicity, only one signal of the two signals constituting the differential signal received by the receiver 22 is shown.

Here, in the Manchester coded signal, every predetermined period, the voltage level is switched from Low level to High level, or High level to Low level. Then, if the further voltage level changes within a predetermined period, the logic value of the signal in the predetermined period represents 1, if the voltage level does not change within a certain predetermined period, the logic value of the signal in the predetermined period represents 0.

For example, in the predetermined period T1 of the time t51 to t52, since the input signal of the receiver 22 (Manchester encoded signal) is falling at the time t51a within a predetermined period T1, the logical value of the input signal of the receiver 22 at a predetermined period T1 represents 1. Similarly, in the predetermined period T3 (from t53 to t54), since the input signal of the receiver 22 in the time t53a within a predetermined period T3 is rising, the logical value of the input signal of the receiver 22 in the predetermined period T3 represents 1. In contrast, in the predetermined period T2 (from t52 to t53), since the input signal of the receiver 22 is not changed within a predetermined period T2, the logical value of the input signal of the receiver 22 at a predetermined period T2 represents 0.

First, in the embodiment of FIG. 3, since no noises are generated, neighboring pulses included in the output signal of the receiver 22 (signal RX) is not colliding. In contrast, in the example of FIG. 4, since the waveform of the input signal is collapsed by the generation of noise, the receiver 22 detects the edge at the timing (time t51b) delayed than the change timing of the original input signal (time t51a), one-shot pulse of the pulse width W It is generated as an output signal. Consequently, in the exemplary embodiment of FIG. 4, neighboring pulses included in the output signal of the receiver 22 (signal RX) has collided (near the time t52). In this case, the receiver 22, it is impossible to obtain accurate data from the differential signal received (input signal).

Therefore, the ECU 1 according to this embodiment, by adjusting the pulse width W to be as short as possible using the pulse width adjusting unit 224, even when noises are generated, to prevent the collision of adjacent pulses, it is possible to accurately receive a differential signal.

### (Pulse Width Adjustment Method)

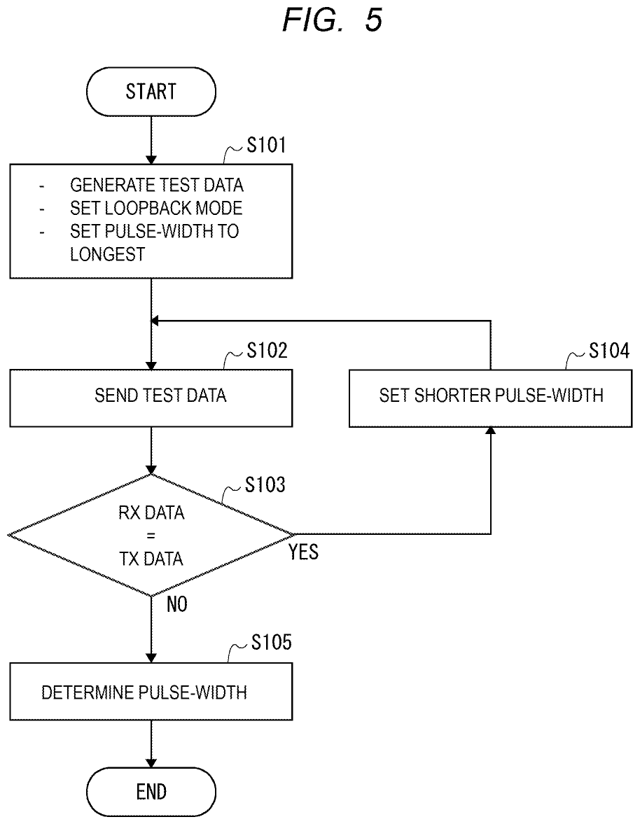

Hereinafter, with reference to FIG. 5, a method for adjusting the pulse width W. FIG. 5 is a flow chart showing the operation of the ECU 1 in a test mode.

First, the operation mode is set to the test mode among the normal operation mode and the test mode (step S101). When the operating mode is set to the test mode, first the test data TX is generated by the CPU 11. Further, the pulse width W is set to the maximum value. Furthermore, the communication unit 20 is set to the loop-back mode. In the loop-back mode, the transmitter 21 provided in the communication unit 20, external of transmitting the transmitted data (test data) TX to the outside, so as to transmit to the receiver 22.

Then, the CPU 11 writes the test-data TX to the RAM 12. The CPU 11 issues a test-data TX transmission demand to the MAC unit 131 of the Ethernet controller 13. The Ethernet controller 13 outputs the test data TX from the MAC unit 131 to the communication unit 20 via the PLCA/PCS/PMA 132, the multiplexer 14 and the IO 15 (step S102).

In the communication unit 20, the transmitter 21 converts the test-data TX into a Manchester-encoded differential. Then, the transmitter 21, rather than transmitting toward the differential signal to the outside, and transmits to the receiver 22 provided in the communication unit 20. Receiver 22 converts the differential signal is a test-data TX into a RZI encoded signal, and outputs a received signal RX. Specifically, the receiver 22 detects the edge of the differential signal is a test data TX, generates a one-shot pulse of the pulse width W at the timing of detecting the edge, and outputs as a received signal RX.

Then, the CPU 11 determines if the test-data TX and the corresponding received-signal RX are consistent (step S103). For example, when it is determined that the test data TX and the corresponding received signal RX are matched (YES of step S103), the test data TX transmitted after the pulse width W is adjusted to be one step shorter (step S104), whether the test data TX and the corresponding received signal RX are matched, it is performed.

Then, if the test data TX and the corresponding received signal RX is determined not to coincide (NO of step S103), the pulse width W set prior to that, as the shortest pulse width capable of receiving a accurately differential signal, is set to the pulse width W used in the normal operation mode (step S105). As described above, the shorter the pulse width W, since the possibility of colliding neighboring pulses even noise is generated is low, the ECU 1 can receive a differential signal with high accuracy.

This tuning of the pulse width W may be performed only once, for example, at the time of assembly of the ECU 1. Thus, as compared with the case where the adjustment of the pulse width W is performed every power up, the power up time is shortened. Alternatively, the adjustment of the pulse width W may be performed every power-up. Thus, it is possible to adjust the pulse width W in consideration of external factors such as temperature and power supply voltage.

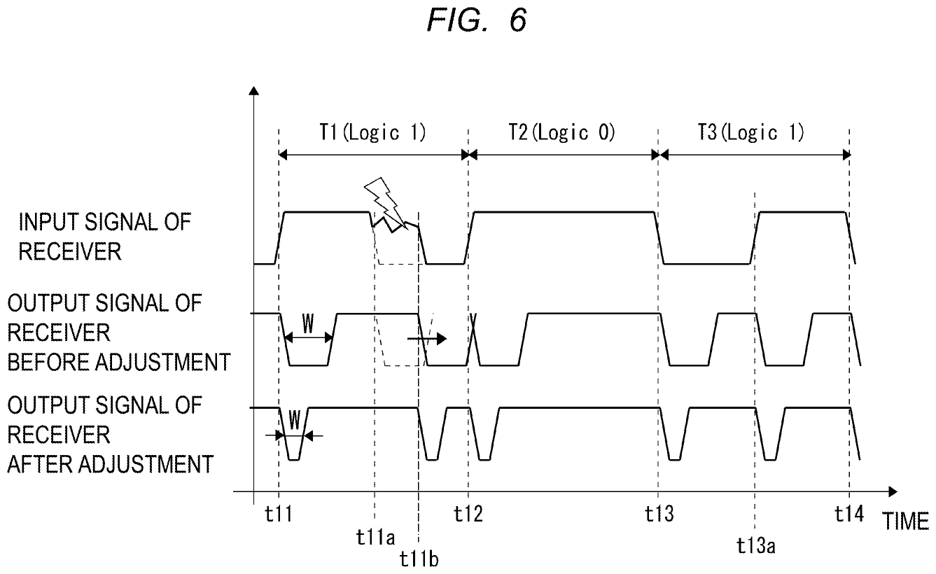

FIG. 6 is a timing chart showing the operation of the ECU 1 after the pulse width adjustment. Incidentally, in FIG. 6, the timing chart of the output signal of the receiver 22 before the pulse width adjustment is also shown. Further, in the example of FIG. 6, for simplicity, only one signal of the two signals constituting the differential signal received by the receiver 22 is shown.

In the example of FIG. 6, since the waveform of the input signal is collapsed by the generation of noise, the receiver 22 detects the edge at the timing (time t11b) delayed than the change timing of the original input signal (time t11a), one-shot pulse of the pulse width W It is generated as an output signal. Here, prior to the pulse width adjustment, since the pulse width W of the one-shot pulse is long, neighboring pulses included in the output signal of the receiver 22 has collided (near time t12). In contrast, after the pulse width adjustment, since the pulse width W of the one-shot pulse is short, neighboring pulses included in the receiver 22 is not colliding (near time t12). Therefore, the receiver 22 can acquire accurate data from the differential signal received.

Thus, the ECU 1 according to the present embodiment, by adjusting the pulse width W to be as short as possible using the pulse width adjusting unit 224, even when noises are generated, to prevent the collision of adjacent pulses, it is possible to accurately receive a differential signal.

In the present embodiment, a case has been described in which the ECU 1 adjusts the pulse width W by actually operating using the test data, but it is not limited thereto. For example, prior to the assembly of the ECU 1, the MCU 10 and the communication unit 20, which are components of the ECU 1, may have individually been tested to determine the pulse width W. In this instance, when the ECU 1 is assembled, the test-result is stored as device-characteristic-information in each of the MCU 10 and the communication unit 20. Therefore, the ECU 1 can determine the pulse-width W without performing a test in the test mode by referring to the device-characteristic-information of each of the MCU 10 and the communication unit 20.

### (Modification of the Receiver 22)

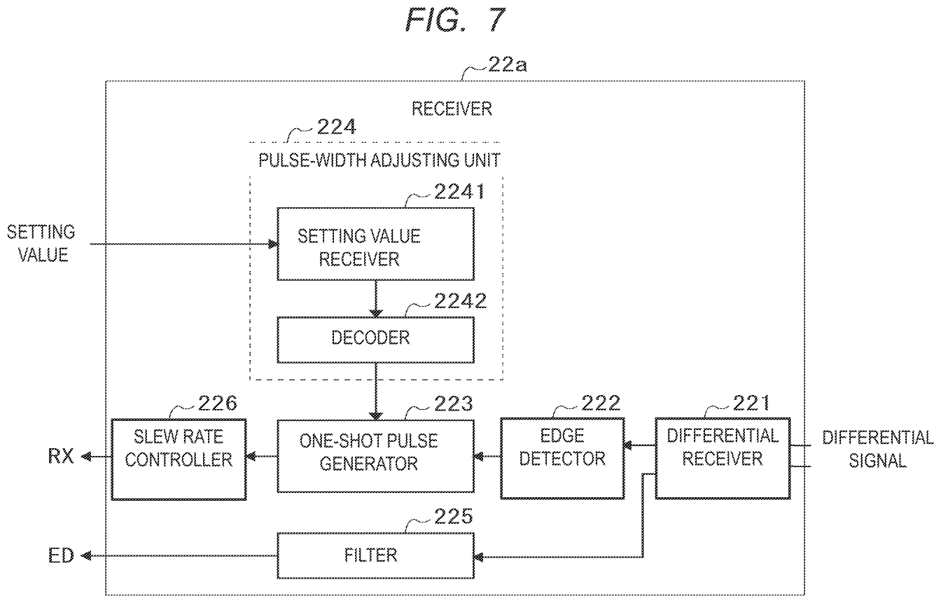

FIG. 7 is a block diagram showing a modification of the receiver 22 as a receiver 22a. Receiver 22a, as compared to the receiver 22 further comprises a slew rate controller 226. The slew rate controller 226 further steepens the fall of the one-shot pulse included in RZI encoded signal. Thus, the reception accuracy of the differential signal is further improved. For another configuration of the receiver 22a, since it is the same as the receiver 22, the explanation thereof will be omitted.

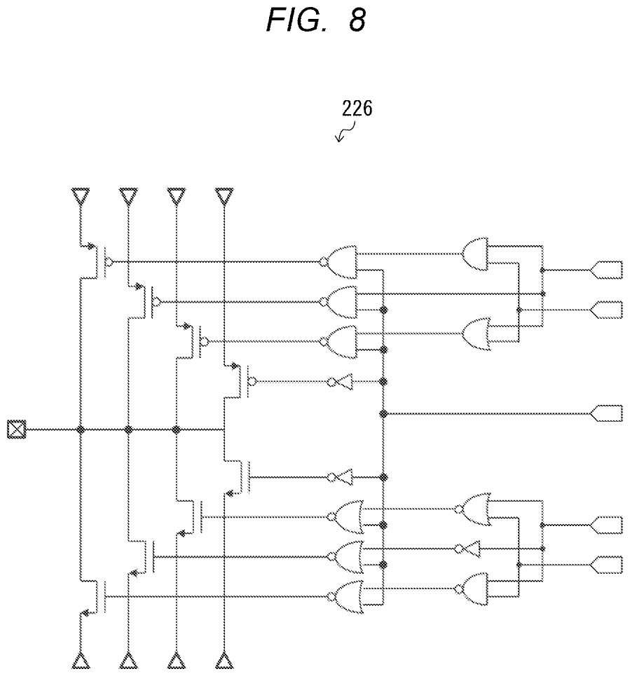

FIG. 8 is a circuit diagram showing a configuration example of a slew rate controller 226. The slew rate controller 226 includes a plurality of CMOS transistors, and a plurality of logical circuits. The slew rate controller 226 is not limited to the circuit configuration shown in FIG. 8, and can be appropriately changed to other circuit configurations capable of realizing the same operation.

### Second Embodiment

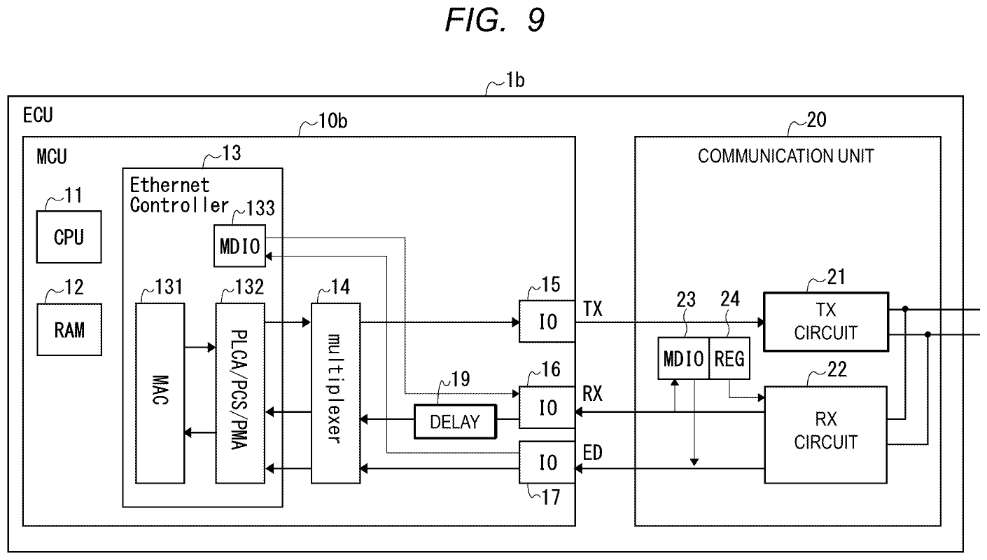

FIG. 9 is a block diagram illustrating an exemplary configuration of an ECU 1b according to the second embodiment. The ECU 1b is equipped with an MCU 10b instead of an MCU 10 as compared to the ECU 1. The MCU 10b further comprises a delay circuit 19 as compared to the MCU 10. The delay circuit 19, RZI encoded signal RX received from the communication unit 20, widens the pulse width of the pulse included in the MCU 10b. Thus, the reception accuracy of the differential signal is further improved. Since the rest of the configuration of the ECU 1b is the same as that of the ECU 1, the explanation thereof will be omitted.

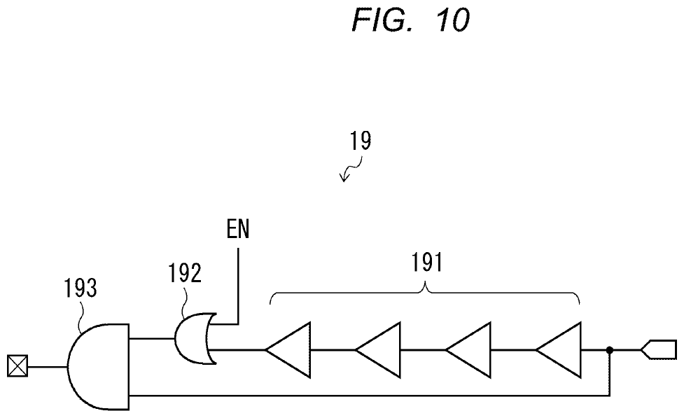

FIG. 10 is a circuit diagram showing a configuration example of a delay circuit 19. As shown in FIG. 10, the delay circuit 19 includes a plurality of buffers 191 in which the input signal is connected in series supplied to the first stage, an OR circuit 192 for outputting a logical sum of the output and the enable signal EN of the final stage of the plurality of buffers 191, and an AND circuit 193 for outputting a logical product of the output of the OR circuit 192 and the input signal of the delay circuit 19. The delay circuit 19 is not limited to the circuit configuration shown in FIG. 10, it can be appropriately changed to other circuit configuration capable of realizing the same operation.

### Third Embodiment

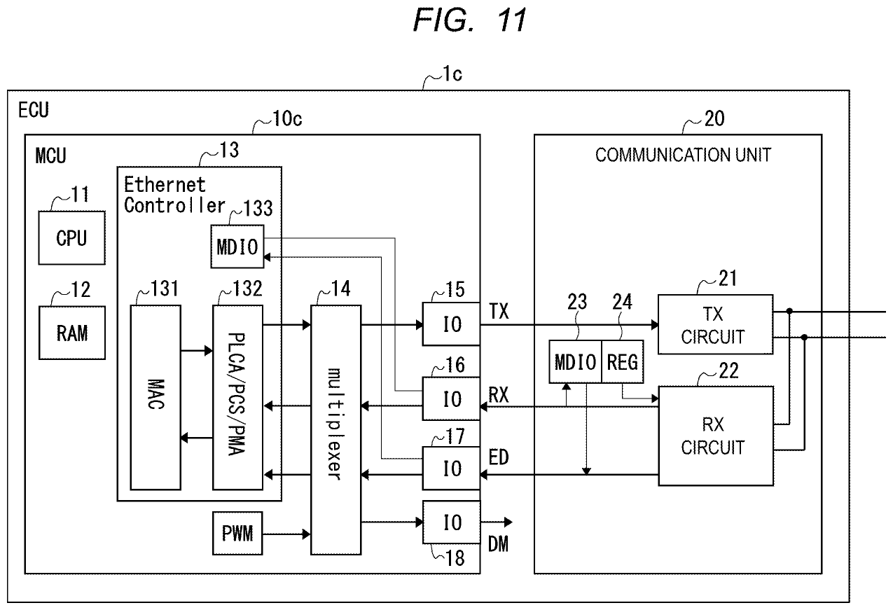

FIG. 11 is a block diagram illustrating an exemplary configuration of an ECU 1c according to a third embodiment. The ECU 1c is equipped with an MCU 10c instead of an MCUn 10 as compared to the ECU 1. The MCU 10c further comprises an IO 18 as compared to the MCU 10. The IO 18 is located close to the IO 16 through which the received-signal RX propagates. More preferably, the IO 18 is positioned adjacently to the IO 16 through which the received signaling RX propagates.

In the test mode, the ECU 1c controls the dummy data DM to propagate to the IO 18 and PAD (not shown) close to the IO 16 and PAD (not shown) to which the received signal RX propagates. Thus, the ECU 1c, as a part of the received signal RX is not damaged affected by the dummy data DM, it is possible to adjust the pulse width W of the pulse included in the received signal RX.

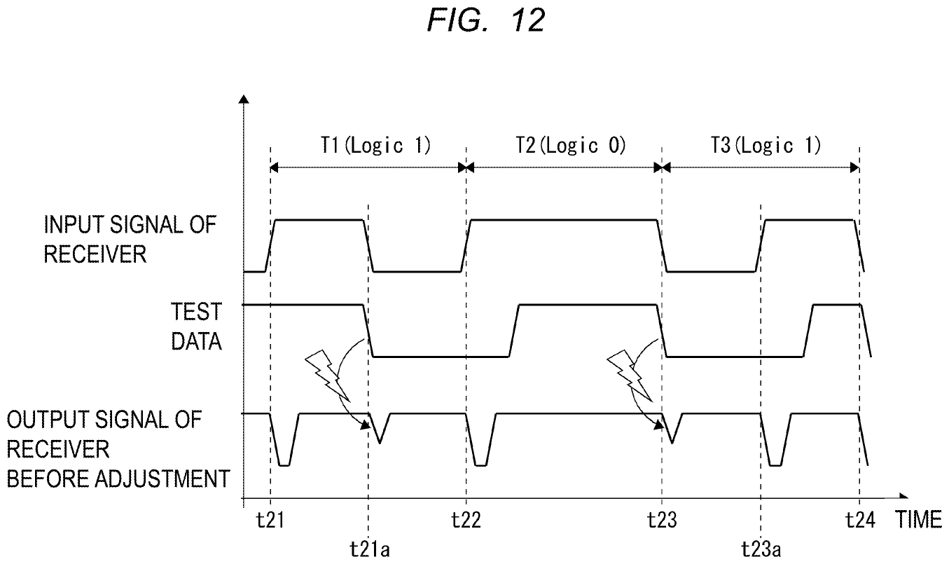

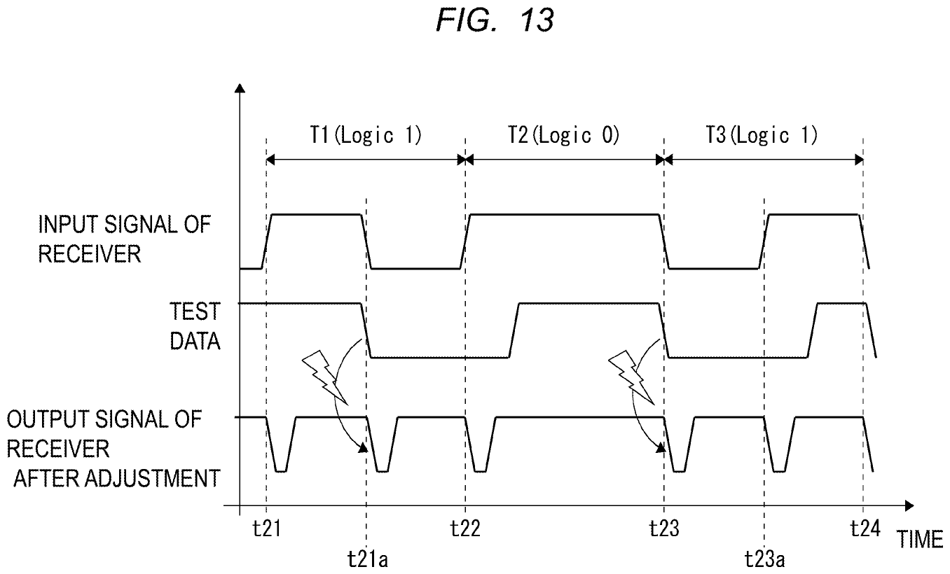

FIG. 12 is a timing chart showing the operation of the ECU 1c prior to pulse-width adjustment. FIG. 13 is a timing chart showing the operation of the ECU 1c after the pulse-width adjustment. In the example of FIGS. 12 and 13, for simplicity, only one of the two signals constituting the differential signal received by the receiver 22 is shown.

First, in the exemplary embodiment of FIG. 12, the pulse-width W is not adjusted in consideration of the effect of the signal change of the dummy data DM. Therefore, a portion of the plurality of pulses included in the output signal of the receiver 22, affected by the signal change of the dummy data DM, has not reached the L-level (time t21a, and time t23a). In this case, the receiver 22 cannot acquire accurate data from the differential signal received.

In contrast, in the embodiment shown in FIG. 13, the pulse-width W is adjusted to take into account the effect of the signal-change of the dummy data DM. Therefore, all of the plurality of pulses included in the output signal of the receiver 22, without being affected by the signal change of the dummy data DM, it has reached the L-level. In this case, the receiver 22 can acquire accurate data from the differential signal received.

Thus, the ECU 1c according to the present embodiment, by adjusting the pulse width W to be as short as possible using the pulse width adjusting unit 224, even when noises are generated, to prevent the collision of adjacent pulses, it is possible to accurately receive a differential signal. Furthermore, the ECU 1c according to the present embodiment, by adjusting the pulse width W in view of the effect of the signals in close proximity, without being affected by the signals in close proximity, it is possible to receive a differential signal with better accuracy.

Although the invention made by the inventor has been specifically described based on the embodiment, the present invention is not limited to the embodiment already described, and it is needless to say that various modifications can be made without departing from the gist thereof.

Furthermore, some or all of the processes of the ECU 1 can be implemented by causing a CPU to execute a computer program.

The program described above includes a set of instructions (or software code) for causing the computer to perform one or more of the functions described in the embodiments when read into the computer. The program may be stored on a non-temporary computer-readable medium or on a tangible storage medium. By way of example and not limitation, computer-readable media or tangible storage media include: RAM (Random-Access Memory), ROM (Read-Only Memory, flash memory, SSD (Solid-State Drive) or other memory techniques, CD-ROM, DVD (Digital Versatile Disc), Blu-ray (registered trademark) disks or other optical disk storage, magnetic cassettes, magnetic tapes, magnetic disk storage or other magnetic storage devices. The program may be transmitted on a temporary computer-readable medium or communication medium. By way of example and not limitation, temporary computer readable media or communication media include electrically, optically, acoustically, or other forms of propagating signals.

What is claimed is:

1. A failure analysis device for analyzing a failure of a semiconductor device having a logic circuit and a memory circuit, comprising:
a storage device for storing fail bit data obtained by testing the memory circuit, and failure diagnosis data obtained by failure diagnosis for the test results of the logic circuit, and
a processor,
wherein the processor extracts a fail I/O from the fail bit data, and extracts data of a memory connection port which is a connection port to the memory circuit from an estimated failure part included in the failure diagnosis data, and determines whether the fail I/O and a port ID included in the data of the memory connection port match or not.

2. The failure analysis device according to claim 1,
wherein the processor converts a fail logical address and the fail I/O included in the fail bit data to a fail physical address, and classifies the fail bit data into any of a plurality of failure modes including a line failure mode and an I/O block failure mode based on the fail physical address and the fail I/O, and determines match/mismatch between the fail I/O value and the port ID value when the classified result of the failure mode is the I/O block failure mode.

3. The failure analysis device according to claim 2,
wherein the processor, when the fail I/O and the port ID match, limits the estimated failure part to a signal transmission path of the memory connection port in the logic circuit, or a signal transmission path of the memory connection port in the peripheral circuit in the memory circuit.

4. The failure analysis device according to claim 2,
wherein the storage device further stores scan chain data including identification information for each of a plurality of scan flip-flops constituting a scan chain and layout arrangement information for each of the plurality of scan flip-flops,
wherein the processor obtains the data corresponding to the memory connection port from the scan chain data as failure scan flip-flop data, and defines a border of the estimated failure part based on the layout arrangement information included in the failure scan flip-flop data.

5. The failure analysis device according to claim 4,
wherein the processor, when the fail I/O and the port ID match, limits the estimated failure part to the signal transmission path of the memory connecting port located at the logic circuit-side than the border.

6. A failure analysis method of a semiconductor device with a logic circuit and a memory circuit:
obtains a fail bit data by a test of the memory circuit, and the failure diagnosis data by failure diagnosis for the test results of the logic circuit stored in the storage device,
extracts a fail I/O from the fail bit data,
extracts data of the memory connection port which is a connection port to the memory circuit from an estimated failure part included in the failure diagnosis data,
determines whether the fail I/O and a port ID included in the data of the memory connection port match or not.

7. The failure analysis method according to claim 6,
converts a fail logical address and the fail I/O included in the fail bit data to a fail physical address,
classifies the fail bit data into any of a plurality of failure modes including a bit failure mode, a line failure mode and an I/O block failure mode based on the fail physical address and the fail I/O,
determines a match/mismatch between the fail I/O and the port ID when the classified result of the failure mode is the I/O block failure mode.

8. The failure analysis method according to claim 7,
limits the estimation failure part to a signal transmission path of the memory connection port in the logic circuit, or a signal transmission path of the memory connection port in a peripheral circuit in the memory circuit, when the fail I/O and the port ID match.

9. The failure analysis method according to claim 7,
further stores scan chain data including identification information for each of a plurality of scan flip-flops constituting a scan chain and layout arrangement information for each of the plurality of scan flip-flops in the storage device,
obtains data corresponding to the memory connection port as failure scan flip-flop data from the scan chain data,
defines a border of the estimated failure part is defined based on the layout arrangement information included in the failure scan flip-flop data.

10. The failure analysis method according to claim 9,
when the fail I/O and the port ID match, limits the estimated failure part to the signal transmission path of the memory connection port located at the logic circuit side than the border.
